(19) United States
(12) Patent Application Publication
(10) Pub. No.: US 2011/0235284 A1
(43) Pub. Date: Sep. 29, 2011

(54) CIRCUIT BOARD

(75) Inventor: WEI-NA HUANG, Tu-Cheng (TW)

(73) Assignee: HON HAI PRECISION INDUSTRY CO., LTD., Tu-Cheng (TW)

(21) Appl. No.: 12/788,318

(22) Filed: May 27, 2010

(30) Foreign Application Priority Data
Mar. 29, 2010 (TW) 99109453

(51) Int. Cl. H05K 1/00

(52) U.S. Cl. 361/748

(57) ABSTRACT

A circuit board includes a printed substrate, a number couple of high signal transmission ports and a number of auxiliary testing ports. The couples high signal transmission ports are electrically connected to printed substrate, and each of the couples high signal transmission ports has an space smaller than 50 mil measured from the centers of the high signal transmission ports. The auxiliary testing ports respectively mounted on the high signal transmission ports, and every two testing ports mounted on a couple of high signal transmission ports are interspaced by an space larger than or equal to 70 mil.

### BACKGROUND

1. Technical Field

The disclosure relates to circuit boards and, particularly, to an easily testable circuit board.

2. Description of Related Art

Manufacture and maintenance of a circuit board require that functionality of various stages of the circuit board be measurable. In circuits layered on the circuit board, it is conventional to lay some test lines electrically connected to the circuits, and extending to predetermined locations of the circuit board, in order to test, measure or trouble-shoot the performance of the circuit board at these predetermined locations. Such test lines on the circuit board have several disadvantages including being localized, expensive, requiring space and adding weight to the circuit board. More importantly, such lines degrade the operation or performance of the circuit board. To overcome the disadvantages, a special test means is applied for directly checking ports of a circuit board and the elements on the circuit board through a number of probes equipped in the test means. However, the circuit board is repeatedly minified to follow the trend of miniaturization, as a result, space between adjacent ports of the circuit board becomes smaller and smaller, requiring extremely precise test machine equipped with extremely thin probes to test the downsized circuit board. Unfortunately, the thinner the probes, the more expensive the test machine. Therefore, testing costs of the circuit board will increase.

Therefore it is desirable for an easily testable circuit board without increasing the space of the circuit board and the test cost.

### BRIEF DESCRIPTION OF THE DRAWINGS

FIG. 1 is a planer view of a circuit board in accordance with an exemplary embodiment.

FIG. 2 is a planer view of a circuit board in accordance with another exemplary embodiment.

### DETAILED DESCRIPTION

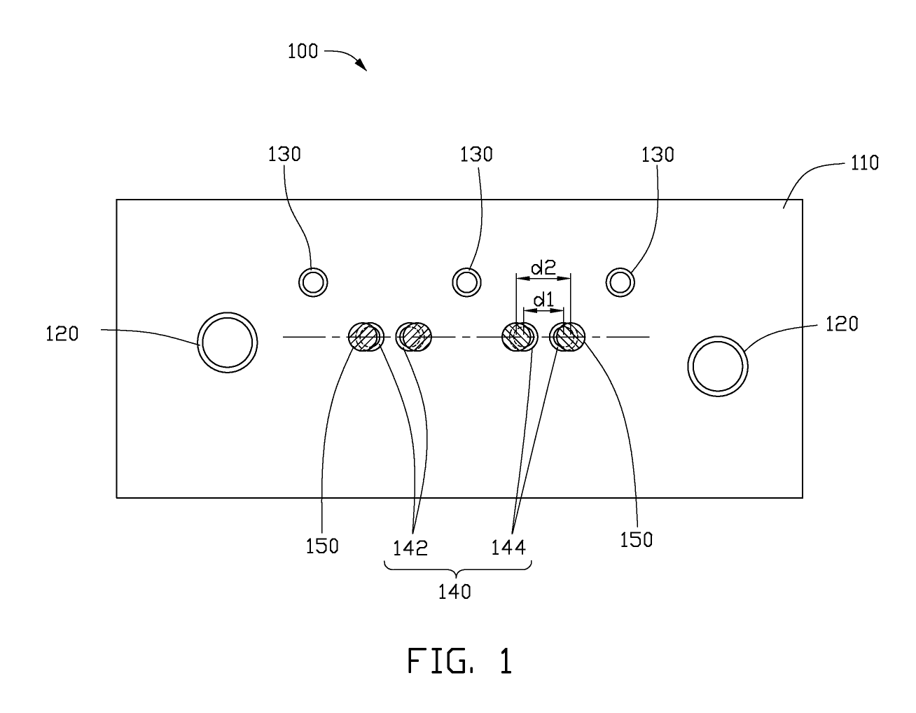

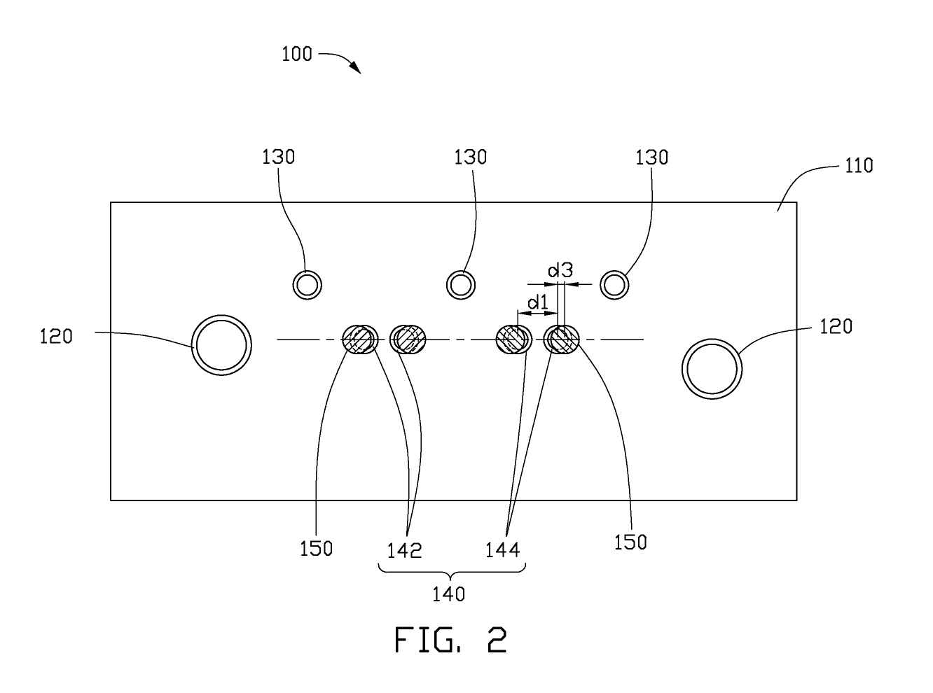

Referring to the FIGS. 1 and 2, the circuit board 100 includes a printed substrate 110 with two first ports 120, three second ports 130, four high speed signal transmission ports 140, and four auxiliary testing ports 150 corresponding to the transmission ports 140.

The printed substrate 110 includes a circuit pattern consisting of etched copper or copper plating or the like for transmission of electrical signals.

The first ports 120 and second ports 130 are electrically connected to the circuit pattern of the printed substrate 110 for transmitting common signals, with low frequencies, powers, and speeds. The first ports 120 and second ports 130 are spaced from one another by more than 70 mil, so that all the ports 120 and 130 can be tested by lower cost common equipment and method.

The high speed signal transmission ports 140 are electrically connected to the circuit pattern of the printed substrate 110. The transmission ports 140 are divided into two sets each including two transmission ports 140 and respectively identifiably indicated as a first set 142 and a second set 144. A space indicated as dl smaller than or equal to 50 mil exists between the transmission ports 140 of each set. The first set 142 and second set 144 are adjacent but spaced from each other by more than 70 mil. In the present disclosure, all ports are circular, and the spaces set forth above between the ports are measured from the centers of the ports.

The auxiliary testing ports 150 are respectively electrically mounted to the transmission ports 140. Each of the testing ports 150 is eccentric from the center of the corresponding transmission port 140. In the present disclosure, the testing ports 150 are designed with a regular form such as circular, rectangular, square, annular, polygonal or the like. The distance between each of the testing ports 150 and the corresponding transmission port 140 is large enough for obtaining a space indicated as d2, between every two testing ports 150, larger than or equal to 70 mil. Whereby, the first set 143 and second set 144 can be tested easily and in a less costly manner by a test equipment via the testing ports 150, because the space between every two testing ports 150 is large enough for implementing the testing by common equipment and method.

Referring FIG. 2, if the spaces dl between every two transmission ports 140 is equal to 50 mil, the center of each testing port 150 is away from the center of the corresponding transmission port 140 by a distance indicated as d3 and is at least more than 10 mil along a straight line that crosses the centers of the transmission ports 140. As such, the spaces between every two testing ports 150 are equal to or larger than 70 mil, suitable for common testing equipment and methods. In addition, the testing ports 150 is directly mounted on the transmission ports 140 that serve as terminal ends far away from the circuit pattern of the print substrate, therefore the transmission quality of the high speed signals in the circuit pattern has few disadvantageous interference or effect from the testing ports 150.

In the present disclosure, a number of testing posts 150 are electrically mounted to the transmission ports 140 thereby magnifying the testing distance of the transmission ports 140 to reduce the cost for testing the circuit board 100 without degradation the performance of the transmission ports 140.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A circuit board comprising:
a printed substrate;
a plurality of couples of high signal transmission ports formed on the printed substrate, each couple of the high signal transmission ports having an space smaller than 50 mil measured from the centers of the high signal transmission ports; and
a plurality of auxiliary testing ports electrically mounted to the high signal transmission ports correspondingly, wherein, every two of the auxiliary testing ports mounted on a couple of the high signal transmission ports are interspaced by an space larger than or equal to 70 mil measured from the centers of the auxiliary testing ports.

2. The circuit board of claim 1, further comprising a plurality of first ports and a plurality of second ports, which are electrically connected to the printed substrate and interspaced with each other by an space larger than 70 mil for allowance of the testing for the circuit board by lower cost common equipment and method.

3. The circuit board of claim 2, wherein the high signal transmission ports are configured for transmitting high signal with relative high frequencies, power and speeds, the first ports and second ports are configured for transmitting common signals with relative low frequencies, power and speeds.

4. The circuit board of claim 1, wherein the testing ports are in regular form.

5. The circuit board of claim 4, wherein the testing ports each are shaped as a circular, a rectangle, a square, an annular, or a regular polygon.

6. The circuit board of claim 5, wherein the high signal transmission ports are in circular form.

7. A circuit board comprising:
a printed substrate;
a plurality of couples of high signal transmission ports formed on the printed substrate, each couple of the high signal transmission ports having an space equal to 50 mil measured from the centers of the high signal transmission ports; and
a plurality of auxiliary testing ports electrically mounted to the high signal transmission ports correspondingly, wherein, the center of each testing port deviates from the corresponding high signal transmission port where the testing port is mounted, by at least 10 mil away from the center of the high signal transmission port along a straight line that crosses the centers of the couple of transmission ports.

8. The circuit board of claim 7, further comprising a plurality of first ports and a plurality of second ports, which are electrically connected to the printed substrate and interspaced with each other by an space larger than 70 mil for allowance of the testing for the circuit board by lower cost common equipment and method.

9. The circuit board of claim 8, wherein the high signal transmission ports are configured for transmitting high signal with relative high frequencies, power and speeds, the first ports and second ports are configured for transmitting common signals with relative low frequencies, power and speeds.

10. The circuit board of claim 7, wherein the testing ports are in regular form.

11. The circuit board of claim 10, wherein the testing ports each are shaped as a circular, a rectangle, a square, an annular, or a regular polygon.

12. The circuit board of claim 11, wherein the high signal transmission ports are annular in shape.
